(19) United States
(12) Patent Application Publication
(10) Pub. No.: US 2007/0034858 A1
(43) Pub. Date: Feb. 15, 2007

(54) Light-emitting diodes with quantum dots

(76) Inventor: Hock Ng, Westfield, NJ (US)

Correspondence Address: Lucent Technologies Inc.;Docket Administrator - Room 3J-219, 101 Crawfords Corner Road, Holmdel, NJ, 07733-3030, US

(21) Appl. No.: 11/202,114

(22) Filed: Aug. 11, 2005

(51) Int. Cl. H01L 31/00; H01L 21/00

(52) U.S. Cl. 257/14; 257/103; 438/46; 257/E33.008

(57) ABSTRACT

An apparatus includes a light-emitting diode. The light-emitting diode has a semiconductor matrix of one or more group III-nitride alloys and quantum dots dispersed inside the matrix. The quantum dots include a group III-nitride alloy different from the one or more group III-nitride alloys of the matrix.

### BACKGROUND

1. Field of the Invention

The invention relates to light-emitting diodes and methods for fabricating and using light-emitting diodes.

2. Discussion of the Related Art

Some conventional semiconductor devices include 2-dimensional (2D) quantum wells that emit light at infrared wavelengths. The 2D quantum wells may be located in a p-n semiconductor junction where electrical pumping will supply charge carriers to excited states of the 2D quantum wells. Subsequently, the de-excitation of these charge carriers via recombinations with carriers of the opposite charge produces light emission. The emitted light has a wavelength that is determined, in part, by the band structure of the 2D quantum wells.

Conventional optical telecommunications systems transmit light in a narrow wavelength window around 1.55 micrometers (μm). In this window, silica glass optical fibers have a low optical absorption coefficient. For that reason, this wavelength window is a low-loss region, which is significantly advantageous for optical telecommunications. In the telecommunications window, some laser sources are available for use in optical transmitters. Nevertheless, it is desirable to have less expensive laser sources for the telecommunications window.

### BRIEF SUMMARY

Various embodiments provide light-emitting diodes (LEDs) having quantum dots therein. Some of the LEDs produce light at wavelengths in the telecommunications window, e.g., between about 1280 nanometers (nm) and about 1600 nm. For that reason, the new LEDs may be inexpensive light sources for telecommunications applications.

In one aspect, an apparatus includes a light-emitting diode. The light-emitting diode has a semiconductor matrix of one or more group III-nitride alloys and quantum dots dispersed inside the matrix. The quantum dots include a group III-nitride alloy differing from the one or more group III-nitride alloys of the matrix.

In another aspect, a method of fabrication includes growing a plurality of quantum dots of a first group III-nitride alloy over a crystalline substrate. The method also includes growing a capping layer of a different second group III-nitride alloy to cover the quantum dots. Portions of the layer are laterally interposed between the quantum dots.

In another aspect, an apparatus that includes a light-emitting diode having a semiconductor stack located therein. The stack has an n-type layer of a group III-nitride alloy, a p-type layer of a group III-nitride alloy, and a plurality of quantum dots of a group III-nitride alloy. The quantum dots are located between the layers and include an indium alloy that differs from the group III-nitride alloys of the layers.

### BRIEF DESCRIPTION OF THE DRAWINGS

Various embodiments are described in the Figures and Detailed Description of Illustrative Embodiments. Nevertheless, the invention may be embodied in various forms and is not limited to embodiments described in the Figures and Detailed Description of Illustrative Embodiments.

FIG. 1 is a cross-sectional view of one embodiment of a light-emitting diode (LED);

FIG. 2 is an oblique view of an exemplary light source incorporating an LED, e.g., the LED of FIG. 1 or 7;

FIG. 3 is a cross-sectional view of an exemplary active light-emission stack for the LED of FIG. 1;

FIG. 4 is an oblique view of an exemplary quantum dot for the active light-emission stacks of FIGS. 1-3;

FIG. 5 illustrates the band structure of gallium nitride (GaN)/indium nitride (InN)/GaN multi-layers;

FIG. 6 is a cross-sectional view of an alternate embodiment of an active light-emission stack for the apparatus of FIGS. 1-2;

FIG. 7 is a cross-sectional view of another embodiment of the light source of FIG. 2 that provides index-guiding light propagating therein;

FIG. 8A is a flow chart illustrating a method of fabricating an active light-emission stack, e.g., the active light-emission stack of FIG. 3;

FIG. 8B is a flow chart illustrating an alternate method of fabricating an active light-emission stack, e.g., the active light-emission stack of FIG. 7;

FIG. 9 is a flow chart illustrating a method of fabricating a light source with an LED, e.g., an LED fabricated according to the method of FIG. 8A or 8B; and

FIG. 10 illustrates intermediate structures formed during the fabrication of a light source according to the method of FIG. 9.

In the Figures and text, like reference numerals indicate elements with similar functions.

In some Figures, relative dimensions of one or more features may be exaggerated to better illustrate the embodiments.

### DETAILED DESCRIPTION OF ILLUSTRATIVE EMBODIMENTS

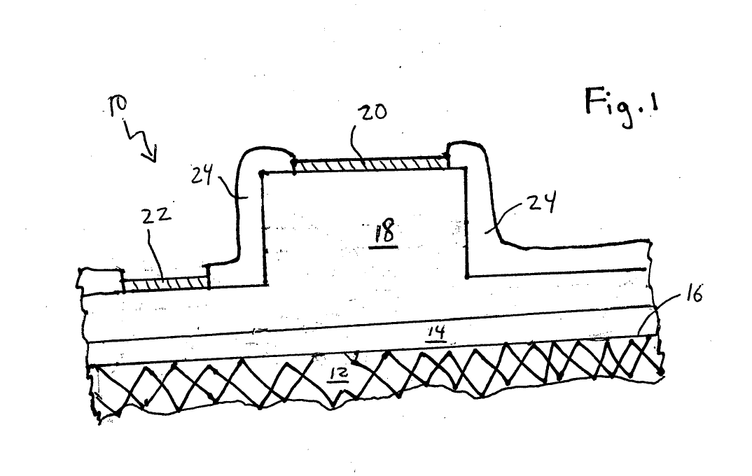

FIG. 1 shows one embodiment of a light-emitting diode (LED) 10 that may emit incoherent or coherent light. The LED 10 is grown on a crystalline group III-nitride buffer layer 14, which is itself grown on a planar top surface 16 of a crystalline substrate 12. Exemplary crystalline substrates 12 include sapphire, silicon, and silicon carbide substrates. The LED 10 includes an active light-emission stack 18 that is grown on a surface of the crystalline group III-nitride buffer layer 14. The active light-emission stack 18 is also fabricated of a crystalline group III-nitride semiconductor. The crystalline group III-nitride buffer layer 14 is a region in which lattice strain partially or completely relaxes. The lattice strain results from a mismatch along the top surface 16 between a fundamental lattice-length of the crystalline substrate 12 and a fundamental lattice-length of the active light-emission stack 18. If a lattice-matched crystalline substrate 12 is available the crystalline group III-nitride buffer layer 14 may be absent.

The LED 10 also includes first and second conducting electrodes 20, 22. The first conducting electrode 20 is in contact with a p-type layer of the active light-emission stack 18. The p-type layer can, e.g., be made by doping the semiconductor with magnesium (Mg). The second conducting electrode 22 is in contact with an n-type layer of the active light-emission stack 18. The n-type layer can, e.g., be made by doping the semiconductor with silicon (Si). The conducting electrodes 20, 22 may, e.g., be fabricated of a metal or a metal multi-layer. Exemplary metal layers and multi-layers include gold (Au), aluminum (Al), platinum (Pt), Al on titanium (Ti), Au on Ti on Al on Ti, ruthenium (Ru) on Pt, and Au on nickel (Ni) or paladium (Pd), but other metal layers and multi-layers may be used. The conducting electrodes 20, 22 are contacts for carrying an electrical current to and from the active light-emission stack 18 to cause light emission. The active light-emission stack 18 functions as a p-n or n-p junction device, i.e., a diode, in a circuit (not shown) that provides a current during operation.

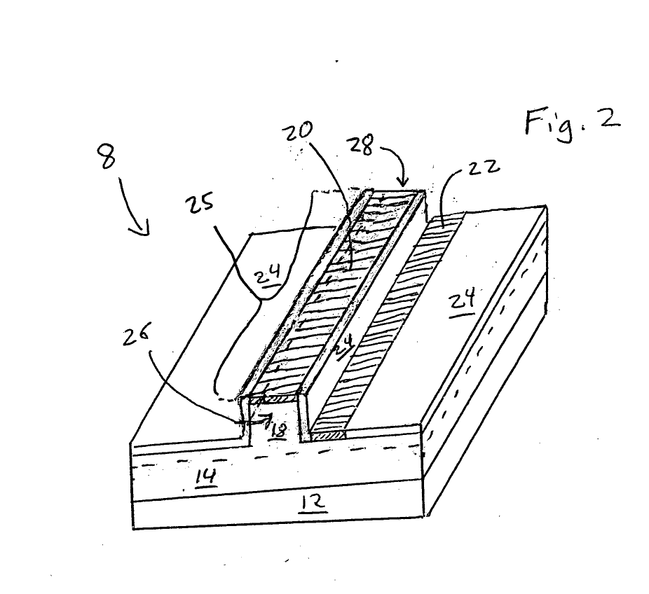

FIG. 2 shows an exemplary light source 8, which incorporates an, e.g., the LED 10 of FIG. 1. The light source 8 has an optical gain medium formed from a portion of the LED 10. The optical gain medium is located in a Fabry-Perot optical cavity. The Fabry-Perot optical cavity includes an optical waveguide 25 and a reflector 26, 28 at each end of the optical waveguide 25. The optical waveguide 25 has an optical core that is formed by group III-nitride of a portion of the LED 10. The optical waveguide 25 has optical cladding that is formed, in part, by the crystalline substrate 12 and, in part, by an optional transparent dielectric layer 24. The transparent dielectric layer 24 may, e.g., be silica glass or silicon nitride or another transparent dielectric. The cavity's light reflectors 26, 28 are end-facets of the optical waveguide 25, e.g., cleaved facets or polished faces of the semiconductor structure.

In some embodiments of the light source 8 provides either gain-guiding or index-guiding of light propagating in the optical waveguide 25 of the Fabry-Perot cavity. In some such embodiments, the light source 8 may, e.g., lase in response to electrical pumping of the LED 10.

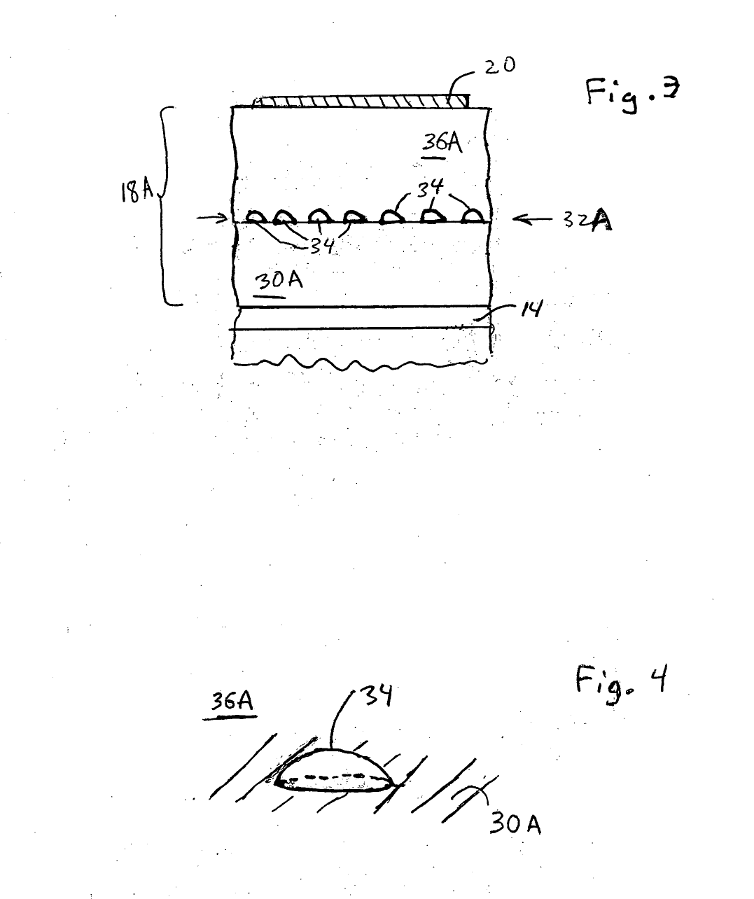

FIG. 3 shows one embodiment 18A of the active light-emission stack 18 of FIG. 1. From bottom to top, the active light-emission stack 18A has a bottom n-type group III-nitride semiconductor layer 30A, an intermediate array 32A of quantum dots 34, and a top p-type group III-nitride semiconductor layer 36A. The bottom n-type semiconductor layer 30A is located directly on the crystalline buffer layer 14, e.g., a GaN or AlN layer. The top and bottom group III-nitride semiconductor layers 36A, 30A are GaₓAl₍₁₋ₓ₎N alloys where 0≦x≦1 or multi-layers of such alloys. Both group III-nitride semiconductor layers 30A, 36A may be the same alloy or alloy multi-layers, e.g., GaN layers. The quantum-dots 34 of the intermediate array 32A may be located along the interface between the n-type and p-type group III-nitride semiconductor layers 30A, 36A or located in a separate intrinsic layer (not shown) of a Ga_{z}Al_{(1-z)}N alloy where 0≦z≦1, e.g., undoped GaN. The active light-emission stack 18A forms a p-n diode.

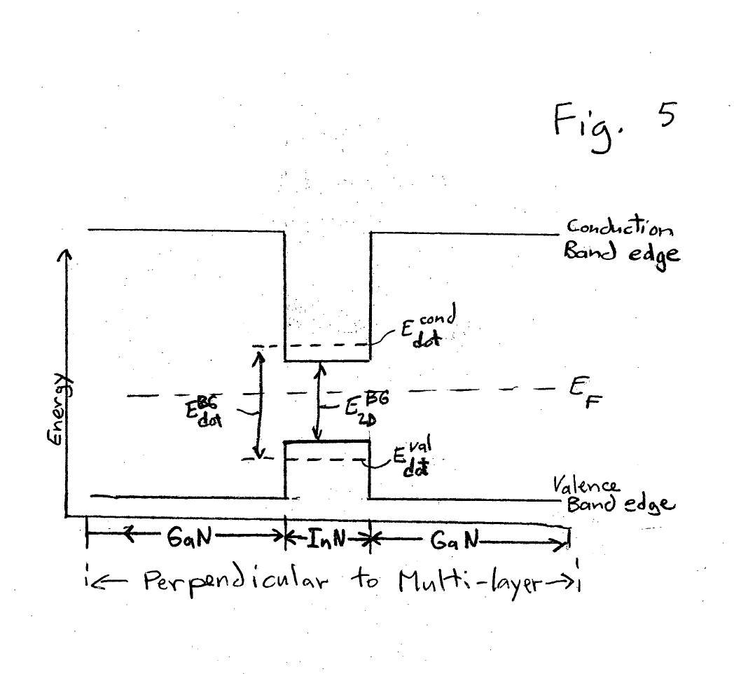

FIG. 4 illustrates an exemplary shape for one of the quantum dots 34 of FIG. 3. The quantum dots 34 can however, have other shapes. The quantum dots 34 are intrinsic or undoped group III-nitride of a different alloy than the alloy of the group III-nitride semiconductor matrix next to the quantum dots 34, e.g., layers 30A, 36A. For the quantum dots 34 exemplary group III-nitride alloys include InᵥGa₍₁₋ᵥ₎N where 0<v≦1, e.g., InN, with less than 10¹⁸ dopant atoms per centimeter cubed. The individual quantum dots 34 are laterally separated by the interposing different semiconductor alloy(s) of the surrounding matrix, e.g., the group III-nitride semiconductor layer 30A and/or layer 36A.

In alternate embodiments, the conductivity p and n types of the bottom and top group III-nitride semiconductor layers 30A, 36A may be reversed. Then, the bottom group III-nitride semiconductor layer 30A is p-type, and the top group III-nitride semiconductor layer 36A is n-type.

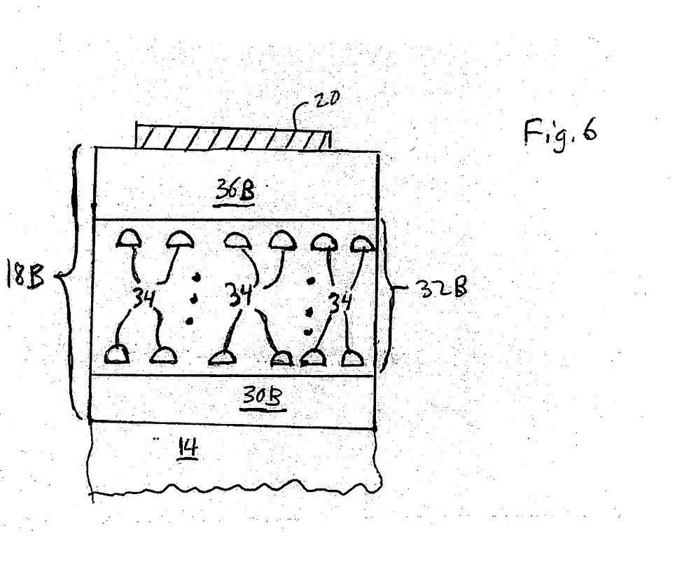

The optical light-emission stack 18A typically has a different light-emission spectrum than a conventional multi-layer structure in which the array of quantum dots 34 is replaced by a continuous 2D layer of the same group III-nitride alloy. In particular, the lateral separation of the quantum dots 34 by the different group III-nitride alloy(s) of the surrounding matrix changes the energy levels of the quantum dots 34. This change is illustrated for an exemplary group III-nitride multi-layer in FIG. 5.

FIG. 5 illustrates the band structure of a multi-layer formed by a top GaN layer, an intermediate InN layer, and a bottom GaN layer. The GaN layers have conduction band edges that are offset to a higher energy than the conduction band edge of the intermediate InN layer, i.e., about 1.6 electron volts (eV) higher. The intermediate InN layer has a valence band edge that is offset to a higher energy than the valence band edges of the GaN layers, e.g., about 1.05 eV higher. For these offsets and appropriate dopant levels in the GaN layers, the Fermi energy (E_{F}) lies between the valence and conduction band of the intermediate InN layer. Thus, electrons can be excited to the conduction band of the intermediate InN layer and will then, de-excite by an inter-band jump to recombine with holes in the valence band of the InN layer.

Since InN is a direct bandgap material, such carrier recombinations can cause the emission of photons with energies about equal to the bandgap of InN. Unfortunately, the band gap of InN is about 0.77 eV, which is lower than the about 0.8 eV that is needed to create a photon with a telecommunications wavelength of 1.55 microns (μm). For that reason, pumping such a GaN/InN/GaN multi-layer will produce light emission at wavelengths longer than 1.55 μm.

In contrast, active light-emission stacks 18, 18A, 18B, 18C of FIGS. 1-3, 6, and 7 replace the continuous 2D intermediate group III-nitride layer by an array of spatially separated quantum dots 34 of the same group III-nitride. In particular, individual ones of the quantum dots 34 are spatially surrounded by a matrix of another group III-nitride alloy. For a quantum dot 34 of InN, an adjacent GaN matrix will confine electrons and holes in the InN thereby functioning as a barrier. In the quantum dot 34, such confinement increases the conduction band edge to the higher level E^{cond}_{dot} and lowers the valence band edge to the lower value E^{val}_{dot} as illustrated in FIG. 5. Thus, a GaN/InN-quantum dots/GaN multi-layer whose intermediate InN is an array of quantum dots 34, will have a band gap, E^{BG}_{dot}, larger than the band gap, E^{BG}_{2D}, of the continuous 2D InN layer in the GaN/InN/GaN multi-layer. Due to the larger bandgap, E^{BG}_{dot}, the GaN/InN-quantum dots/GaN multi-layer will also emit higher energy photons in response electrical pumping. For suitably small and sufficiently widely separated InN quantum-dots, such a structure may be able to emit photons with energies of about 0.8 eV, e.g., photons at in the telecommunications window where wavelengths are shorter than about 1.60 μm.

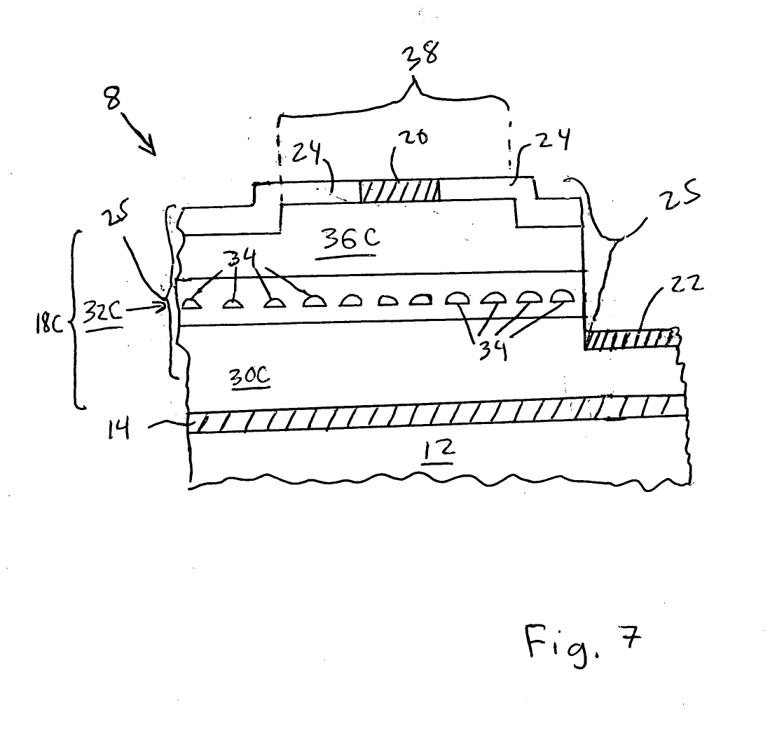

FIG. 6 shows an alternate embodiment 18B of the active light-emission stack 18 for the LED 10 of FIG. 1 and/or the light source 8 of FIG. 2. From bottom to top, the optical amplification stack 18B includes crystalline n-type group III-nitride semiconductor layer 30B, intermediate intrinsic semiconductor layer 32B, and p-type group III-nitride semiconductor layer 36B. The n-type and p-type semiconductor layers 30B, 36B may, e.g., have substantially the same-doped group III-nitride semiconductor compositions as the respective bottom and top group III-nitride semiconductor layers 30A, 36A of FIG. 3. The intermediate semiconductor layer 32B includes a crystalline matrix of the same or a different group III-nitride alloy as in the semiconductor layers 30B, 36B and the quantum dots 34 dispersed therein. The active light-emission stack 18B forms a p-n structure, i.e., a diode.

The intermediate semiconductor layer 32B includes a vertical stack of 2D arrays of quantum dots 34. The quantum dots 34 are formed of a different group III-nitride alloy than the surrounding group III-nitride semiconductor matrix of the layer 32B. For a GaN semiconductor matrix or more generally a GaₓAl₍₁₋ₓ₎N matrix with 0≦x≦1. The quantum dots 34 are formed of an intrinsic In-containing alloy, e.g., In N or In_{w}Ga_{(1-w)}N with 0<w≦1. The In-containing alloy of the quantum dots 34 has less than about 10¹⁸ dopant atoms per centimeter cubed. The adjacent semiconductor matrix of the layer 32B vertically and horizontally isolates individual ones of the quantum dots 34. For appropriate heights and widths, the quantum dots 34 can emit light in the above telecommunications wavelength window. Furthermore, the vertical stacking of the arrays of quantum dots 34 means that the active light-emission stack 18B may hold a larger number of quantum dots 34 than the active light-emission stack 18A of FIG. 3. Thus, the light source 8 may provide more intense light when the active light-emission stack 18A is replaced therein by the active light-emission stack 18B.

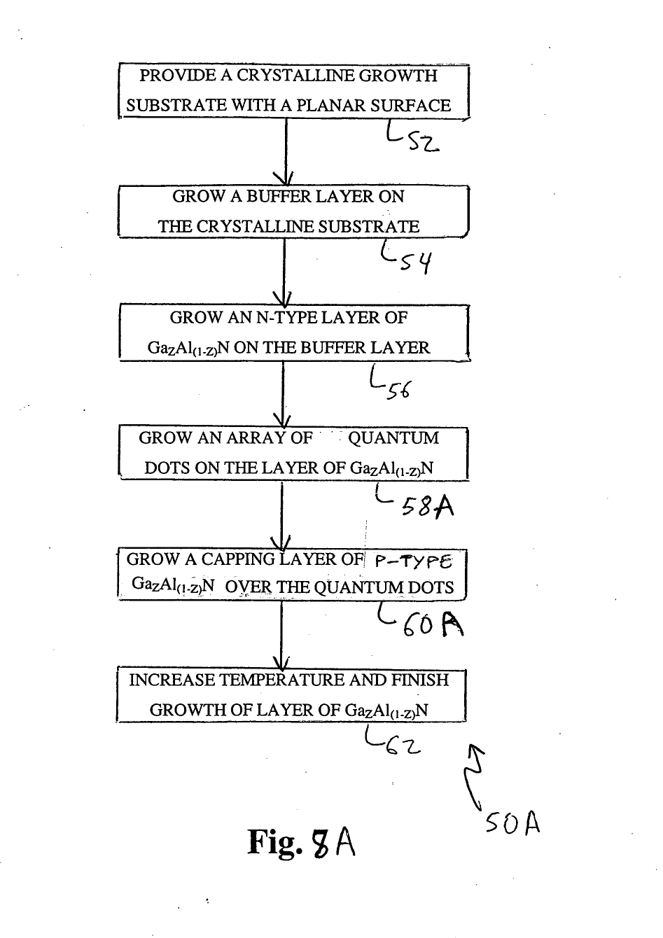

FIG. 7 shows an embodiment of the light source 8 of FIG. 2 that provides vertical and lateral index guiding of light that is propagating in the optical waveguide 25 of the source's Fabry-Perot cavity. In particular, the embodiment includes a crystalline substrate 12, a crystalline buffer layer 14, conducting electrodes 20, 22, dielectric layer 24, and group III-nitride active light-emission stack 18C. The crystalline substrate 12 may, e.g., be suitably oriented crystalline sapphire, silicon, or silicon carbide as described with respect to the LED 10 of FIG. 1. The crystalline buffer layer 14 may, e.g., be an AlN or GaN layer with a thickness in the range of about 20 nanometers (nm) to about 50 nm, e.g., 20 nm. The conducting electrodes 20, 22 may, e.g., be single or multiple metal layers as already described with respect to the LED 10 of FIG. 1. The optional dielectric layer 24 may be a conformal layer SiO₂ or Si₃N₄ with a thickness of about 0.1 μm to about 0.3 μm.

In the active light-emission stack 18C, both the vertical multi-layer structure and the lateral cross-sectional shape are adapted for index-guiding of light therein. That is, these features provide index-guiding to light propagating in the optical waveguide 25 of the light source's Fabry-Perot cavity.

The vertical multi-layer structure of the active light-emission stack 18C includes a bottom n-type AlₓGa₍₁₋ₓ₎N layer 30C, a middle intrinsic group III-nitride layer 32C, and a top p-type Al_{y}Ga_{(1-y)}N layer 36C. The bottom n-type AlₓGa₍₁₋ₓ₎N layer 30C may, e.g., have a thickness of about 1 μm or more and an alloy parameter “x” in the range [0, 0.25], e.g., x=0.15. The n-type layer 30C is, e.g., be doped with about 10¹⁷-10¹⁸ n-type Si atoms per centimeter-cubed. The middle intrinsic group III-nitride layer 32C may, e.g., include an intrinsic GaN semiconductor matrix with a thickness of about 0.1 μm to about 0.2 μm. In the intrinsic GaN, concentrations of dopant atoms are about 10¹⁵-10¹⁶ or less of such atoms per centimeter cubed. The semiconductor matrix includes one or more horizontal arrays of quantum dots 34 distributed therein. The quantum dots 34 are formed of an intrinsic group III-nitride alloy of indium, e.g., InN or In_{w+z}Ga_{(1-w)}Al_{(1-z)}N with w and z in the range [0, 1] and w+z>0. Thus, the quantum dots 34 are formed of a different alloy than the surrounding semiconductor matrix of the layer 32C. In intrinsic In alloys, concentrations of dopants can be as high as about 10¹⁷ to 10¹⁸ dopant atoms per centimeter cubed. The top p-type Al_{y}Ga_{(1-y)}N layer 36C can, e.g., have a thickness of about 0.5 μm and an alloy parameter “y” in the range [0, 0.25]. The p-type layer 36C can, e.g., be doped with about 10¹⁸-10²⁰ Mg atoms per centimeter cubed. The multi-layer group III-nitride alloy structure has a vertical refractive-index profile that tends to index-guide light so that the light is localized around the middle intrinsic group III-nitride layer 32C. That is, the light is index-guided to be concentrated adjacent the quantum dots 34 and surrounding semiconductor matrix, which forms the optical gain medium of the light source 8.

The lateral cross-sectional shape of the active light-emission stack 18C also includes a ridge 38 along the top surface of the top Al_{y}Ga_{(1-y)}N layer 36C. The ridge 38 may, e.g., have a height of about 0.25 μm and a lateral width of about 2 μm to about 10 μm. The optical waveguide 25 may, e.g., have a total lateral width of about 30 μm to about 50 μm. For such a cross-sectional profile, the relatively high refractive index of the ridge 38 aids to laterally index-guide light that is propagating in the optical waveguide 25 of FIG. 2.

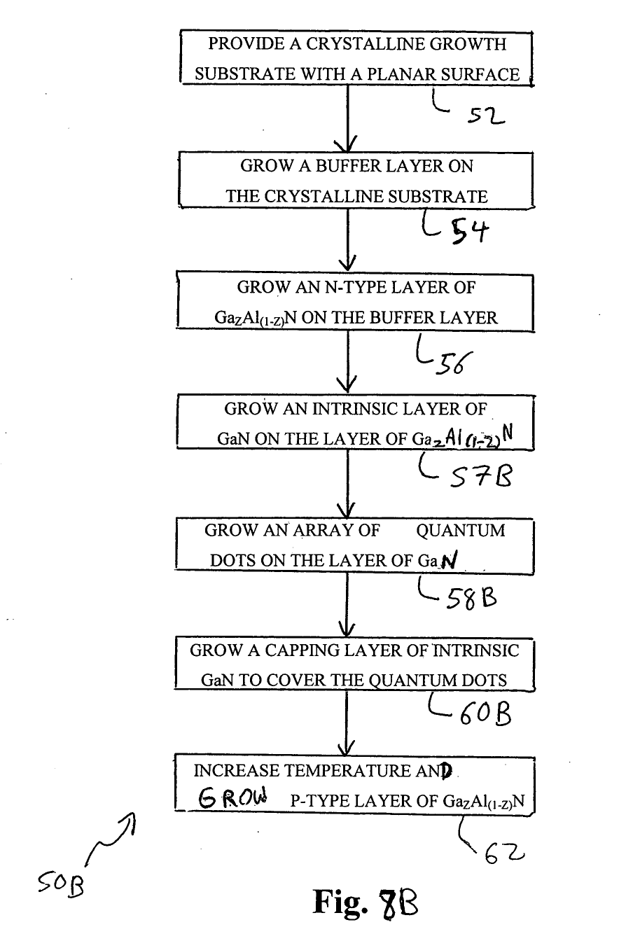

FIG. 8A illustrates one method 50A for fabricating embodiments of the active light-emission stack 18A of FIGS. 1 and 3.

The method 50A includes providing a crystalline growth substrate having a planar growth surface, e.g., the crystalline substrate 12 and top surface 16 (step 52). The crystalline growth substrate may be sapphire (i.e., Al₂O₃), silicon, or another substrate, e.g., 6H—SiC or 4H—SiC. For sapphire and SiC, the planar growth surface is the (0001) lattice plane. For silicon, the planar growth surface is the (111) lattice plane.

The method 50A includes epitaxially growing a crystalline buffer layer of AlN or GaN on the growth surface of the crystalline growth substrate (step 54). This growth involves performing a conventional epitaxial process such as molecular beam epitaxy (MBE). The epitaxial growth produces a thin crystalline buffer layer with a thickness of about 20 nm to about 50 nm. The crystalline buffer layer lattice relaxes strain resulting from the growth of group III-nitride on a lattice-mismatched crystalline growth substrate. If a lattice-matched crystalline growth substrate is available, the crystalline buffer layer is not necessary.

Next, the method 50A includes epitaxially growing an n-type layer of Ga_{z}Al_{(1-z)}N with 0≦z≦0.25, e.g., z=0.15, on the crystalline buffer layer, e.g., the layer 30A (step 56). This epitaxial growth step forms a crystalline layer whose thickness is about 0.5 μm to about 4.0 μm. During the growth, the crystalline growth substrate is kept at a temperature of about 650° C. to about 800° C.

During the epitaxial growth step 56, several sources provide materials to the growing layer. One set of sources provides the Ga, Al, In, and N. The source for the Ga may, e.g., be a model ABN-135 effusion cell of Riber, 133 boulevard National, BP 231, 92503 Rueil Malmaison Cedex, France (www.riber.com). The Ga effusion cell is operated at a temperature of about 980-1030° C. The source for the Al may be another Riber model ABN-135 effusion cell operated at a temperature of about 1020-1120° C. The source for the N may be a plasma source operated at an RF power of about 250 to 350 watts and a gas flow rate of about 0.5-0.9 standard centimeters cubed per minute (sccm). An exemplary plasma source is the model RFB-RB3, Serial No. 001206, plasma source of ADDON, 19 rue des Entrepreneurs, 78420 Carrieres sur seine, France (contact@addon-mbe.com). A last source provides n-type dopant atoms, e.g., Si, to simultaneously produce a dopant concentration of about 10¹⁷-10¹⁸ n-type atoms per centimeter-cubed. The source for the Si may be another Riber model ABN-135 effusion cell operated at a temperature of about 900-1100° C.

Next, the method 50A includes growing an array of quantum dots of an indium-nitride alloy, e.g. the quantum dots 34 (step 58A). The quantum dots are grown on a free surface of the n-type layer of Ga_{z}Al_{(1-z)}N. During the growth, the substrate's temperature is kept below about 600° C., e.g., 400° C.-550° C. so that the quantum dots do not degrade. For example, InN decomposes at higher temperatures of about 500° C.-600° C. The source for the In may be another Riber model ABN-135 effusion cell operated at a temperature of about 700-850° C.

The epitaxial growth of step 58A produces quantum dots that are an alloy of indium, nitrogen and optionally gallium and/or aluminum, e.g., InN. Alloys that include Ga or Al typically have a larger bandgap than InN thereby enabling the quantum dots to have potentially longer light-emission wavelengths. The growth step produces quantum dots with sizes suitable to emit light at a preselected wavelength or in a preselected range of wavelengths. For example, the quantum dots may be designed to emit light in the telecommunications window of 1280 nm to about 1600 nm. The quantum dots may be grown to heights of about 1 nm-5 nm, e.g., 2 nm, and may be grown to diameters of about 10 nm-50 nm. During the step 58A, growth conditions cause three-dimensional (3D) growth of islands rather than a 2D growth of a continuous a continuous layer.

One method for producing 3D growth of InN islands involves alternating the performance of first and second growth steps, e.g., in an MBE chamber model No. 32P of the Riber Company. In the first growth step, the growth surface is subjected to In vapor for 30-60 seconds while the nitrogen source is blocked. During this step, the In effusion cell is hotter than about 670° C., e.g., about 740° C. to about 790° C. In the second growth step, the growth surface is subjected to nitrogen for about 30-60 seconds while the In effusion cell is blocked. During this step, nitrogen gas has a flow rate of about 0.4-0.6 sccm and is in a RF background power of about 200-350 watts of RF power that produces a plasma. The performance of the first and second growth steps is repeated until the InN quantum dots have a desired size.

Another method for producing such 3D growth of InN islands involves producing conditions for a Stranski-Krastanov growth. During a Stranski-Krastanov growth, the growth surface is continuously exposed to both In and N such that the growth switches from a 2D mode to a 3D mode after a few bilayers of InN have been deposited.

Next, the method 50A includes epitaxially growing a thin intrinsic or p-type capping layer of the Ga_{z}Al_{(1-z)}N alloy with 0<z≦0.25, e.g., GaN, over the array of quantum dots (step 60A). The capping layer preferably has a thickness of about 20 nm to about 50 nm. During this growth, the crystalline substrate is maintained at about the same temperature used to grow the quantum dots, e.g., about 450° C. to about 550° C. for InN quantum dots. Due to this low growth temperature, the quantum dots do not decompose during the growth of the capping layer. During the growth, the Ga_{z}Al_{(1-z)}N may be doped with p-type impurity such as magnesium (Mg) to a concentration of about 1×10¹⁸ to about 1×10²⁰ impurity atoms per centimeter cubed. A Riber model ABN-135 effusion cell operated at a temperature between 250° C. and 400° C. can be a Mg source for the p-type doping.

Next, the method 50A includes increasing the substrate temperature to about 650° C.-750° C. and continuing the epitaxial growth of a p-type layer of the same or of a different Ga_{z}Al_{(1-z)}N alloy, e.g., layer 36A, at this higher temperature (step 62). The epitaxial growth is stopped when the top p-type Ga_{z}Al_{(1-z)}N has a thickness of about 0.2 μm to about 0.5 μm.

FIG. 8B illustrates an exemplary method 50B for fabricating an embodiment of the active light-emission stack 18C of FIG. 7.

The method 50B involves performing steps 52, 54, and 56 as described with respect to the method 50A of FIG. 8A. These steps produce, e.g., a multi-layer structure with the layers 30C and 14 and the crystalline substrate 12 as shown in FIG. 7.

Next, the method 50B includes epitaxially growing a layer of intrinsic GaN on free surface of the n-type layer of Ga_{z}Al_{(1-z)}N (step 57B). The resulting layer of intrinsic GaN may, e.g., have a thickness of about 0.5 μm to about 0.1 μm and can have a dopant level of about 10¹⁵-10¹⁶ dopant atoms per centimeter cubed. An example of the produced layer of GaN is the portion of the layer 32C, which is located below the array of the quantum dots 34 in FIG. 7.

Next, the method 50B includes growing an array of quantum dots, e.g. the quantum dots 34, on a free surface of the layer of intrinsic or undoped GaN (step 58B). The growth produces quantum dots that are undoped group III-nitride alloys of In and uses growth conditions already-described with respect to above step 60A. In particular, the growth is at a low temperature that does not decompose the In alloy and is controlled to produce 3D island growth rather than 2D layer growth. The growth may, e.g., produce quantum dots with heights of about 1-5 nm high, e.g., 2 nm, and diameters of about 10-50 nm or quantum dots of other sizes as appropriate to the desired emission-spectrum. For example, the quantum dots may be grown to sizes appropriate for emitting light in the above-described telecommunications window.

Next, the method 50B includes epitaxially growing a capping layer of intrinsic or undoped GaN over the array of quantum-dots (step 60B). The capping layer of intrinsic GaN may, e.g., have a thickness of about 0.5 μm to about 0.1 μm and can have a dopant level of about 10¹⁵-10¹⁶ dopant atoms per centimeter cubed. The capping layer laterally surrounds individual quantum dots with a matrix of GaN and covers the quantum dots. An example of the capping lay is, e.g., be the upper portion of the layer 32C in FIG. 7.

During the growth of the first 20 nm-50 nm of the capping GaN layer, the crystalline growth substrate is maintained at the temperature that was used to grow the quantum dots. For InN quantum dots, the temperature is kept below about 600° C., e.g., 450° C.-550° C. so that the quantum dots do not degrade. The low growth temperature reduces decomposition of the quantum dots during the growth of the capping layer of GaN.

Next, the method 50B includes increasing the substrate temperature to about 650° C.-750° C. and epitaxially growing a p-type layer of the Ga_{z}Al_{(1-z)}N alloy, e.g., the layer 36B of FIG. 7 where 0<z≦0.25 (step 62). This growth may, e.g., produce a p-type layer of Ga_{z}Al(1−z)N with a thickness of about 0.2 microns to about 0.5 microns. Conditions for this growth were already described with respect to the step 62 of the method 50A.

Alternate embodiments of the fabrication method 50B involve repeating steps 58B-60B several times to produce vertically stacked arrays of quantum dots of the same InN-alloy in a matrix of intrinsic GaN, e.g., as in the layer 32B of FIG. 6. The vertical profile is a sequence of the form: n-type Ga_{z}Al_{(1-z)}N/[undoped GaN/InN-alloy quantum dots]/[undoped GaN/InN-alloy quantum dots]/[undoped GaN/InN-alloy quantum dots]/ . . . /undoped GaN/p-type Ga_{z}Al_{(1-z)}N. The total thickness of the vertical sequence may, e.g., be 1-2 μm thick. In the vertical sequence, the intrinsic GaN layers may also be replaced by layers of another intrinsic group III-nitride alloy different from the InN-alloy of the quantum dots. In such embodiments, the bottom n-type and top p-type Ga_{z}Al_{(1-z)}N layers have the above-described dopant concentrations. Such a vertical stacking of the arrays of InN quantum dots should typically increase the intensity of the LED light source.

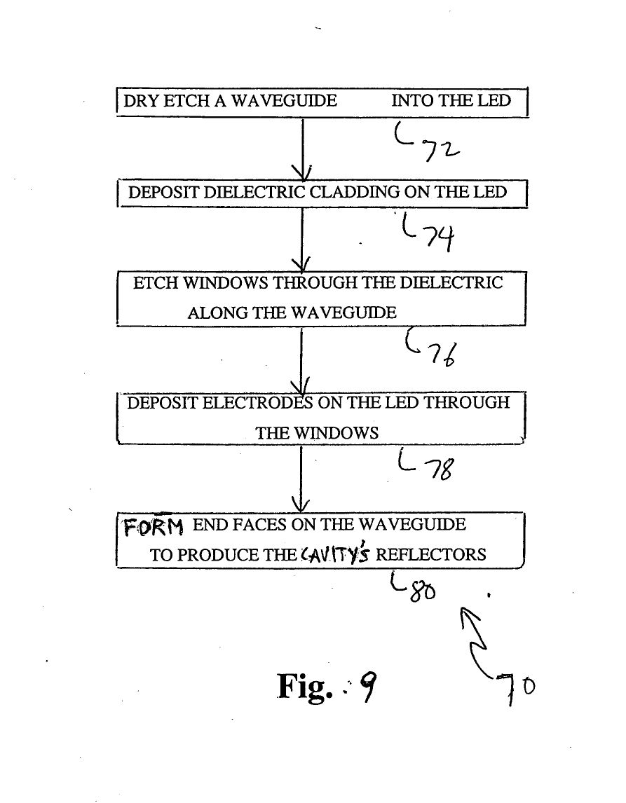

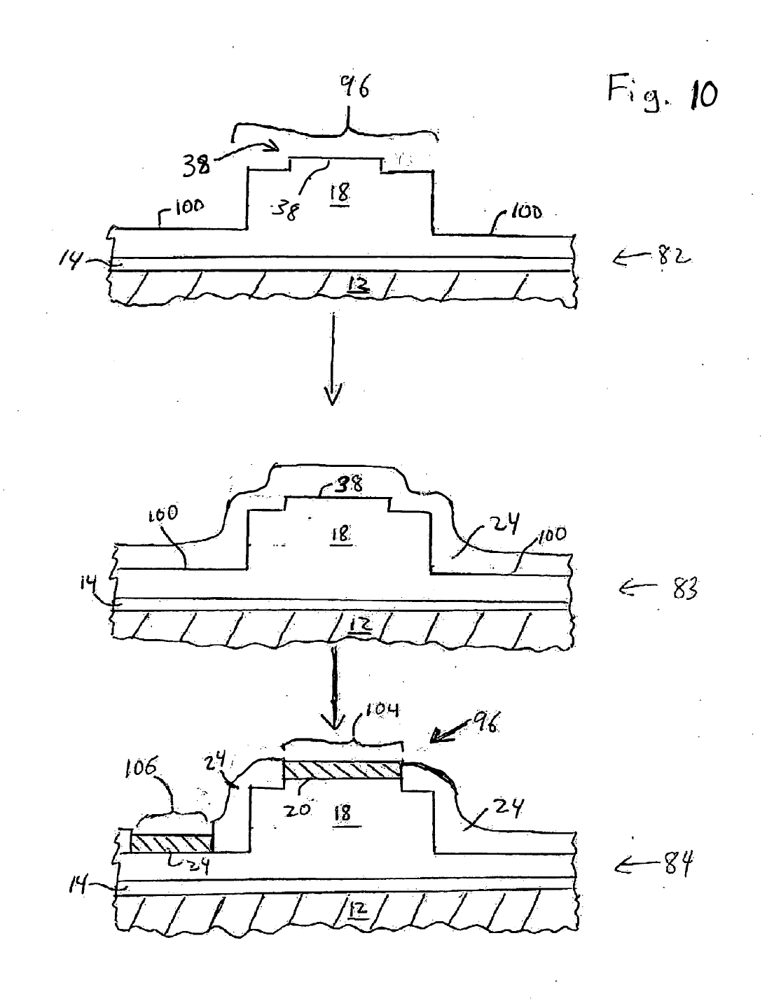

FIG. 9 illustrates a method 70 for fabricating a light source, e.g., the light source 8 of FIGS. 2 and 7. The light source includes a Fabry-Perot cavity with an optical waveguide and may, e.g., be a laser. The fabrication method 70 produces intermediate structures 82, 83, 84 as shown in FIG. 10.

The method 70 includes performing one or more dry etches to form a rectangular waveguide structure 96 and an area for a lower conducting electrode on an active light-emission stack of the LED, e.g., the light-emission stack 18C, thereby forming the LED structure 82 (step 72). Each dry etch is controlled by a conventional lithographic mask and uses a conventional process, e.g., inductively-coupled reactive ion etching based on a chlorine (Cl)/argon (Ar) gas mixture.

The etch step may involve one or two dry etches. One dry etch always forms the optical waveguide structure 96 by exposing a portion of the bottom layer of n-type group III-nitride of the light-emission stack, e.g., the bottom layer 30C. An optional second dry etch may define an index-guiding ridge 38 over the center of the optical waveguide structure 96. The ridge 38 may, e.g., be about 0.5 μm high. Defining the ridge involves etching away an optical cladding portion of the top layer of p-type group III-nitride, e.g., part of the top layer 36C. The second etch produces a cross-sectional shape that laterally index-guides light in the optical waveguide structure 96. The cross-sectional shape is, e.g., suitable for the optical waveguide 25 of the light source 8 shown in FIGS. 2 and 7.

Next, the method 70 includes depositing a conformal layer 24 of transparent dielectric on the top surface 100 of the LED structure 82 thereby producing the structure 83 (step 74). The dielectric has a refractive index that is suitable for an outer optical cladding of the optical semiconductor waveguide structure 96. The thickness of the dielectric layer can be between about 0.1 μm and about 0.3 μm. For the layer 24, exemplary dielectrics include doped or undoped silica glass and doped or undoped silicon nitride. Methods for depositing such dielectrics are known to those of skill in the art.

Next, the method 70 includes dry etching windows 104, 106 through the dielectric layer 24 along the length of the optical waveguide structure 96 (step 76). One window 104 is over the ridge 38 on the central portion of the optical waveguide structure 96, and the other window 106 is adjacent to the optical waveguide structure 96.

Next, the method 70 includes forming conducting electrodes 20, 22 on the group III-nitride semiconductor of the LED structure exposed via the windows 104, 106 thereby producing the LED structure 84 (step 78). Forming the conducting electrodes 20, 22 involves, e.g., performing a mask-controlled evaporation-deposition and may involve depositing one or multiple metal layers. Examples of conducting electrodes 20, 22 are described with respect to the LED 10 of FIG. 1 and may include metal layer or multi-layers such as Au, Al, Al on Ti, or Pt, Au on Ni, or Ru on Pt.

Finally, the method 70 includes cleaving or polishing end faces on the optical waveguide structure 96 to produce reflectors at opposite ends of a Fabry-Perot cavity, e.g., the facets 26, 28 of FIG. 2 (step 80).

To generate light from the LED 10 of FIG. 1 or light sources 8 of FIG. 2 or 7, a current is pumped between the conducting electrodes 20, 22. The current may excite electrons into levels of the conduction band in the quantum dots 34. The electrons may then, emit light by subsequently recombining with holes from the valence bands of the quantum dots 34.

In other embodiments roles of n-type and p-type doping are interchanged. That is, in the light-emission stacks 18, 18A-18C of FIGS. 1-3 and 6-7 , the top layer of group III-nitride, e.g., layers 36A-36C, is n-type, and the bottom layer of group III-nitride, e.g., the layers 30A-30C, is p-type.

From the disclosure, drawings, and claims, other embodiments of the invention will be apparent to those skilled in the art.

What is claimed is:

1. An apparatus, comprising:
a light-emitting diode having a semiconductor matrix of one or more group III-nitride alloys and quantum dots dispersed inside the matrix, the quantum dots comprising a group III-nitride alloy different from the one or more group III-nitride alloys of the matrix.

2. The apparatus of claim 1, wherein the quantum dots comprise indium.

3. The apparatus of claim 2, wherein the matrix comprises a gallium alloy.

4. The apparatus of claim 2, wherein the matrix comprises an aluminum alloy.

5. The apparatus of claim 2, wherein the quantum dots are dispersed between n-type and p-type regions of the diode.

6. The apparatus of claim 5, wherein the matrix is sandwiched between n-type and p-type regions of the diode and has a higher refractive index semiconductor alloy than the n-type and p-type regions.

7. The apparatus of claim 1, wherein the quantum dots are distributed in layers that form a vertical stack along a direction between an n-type region of the diode and a p-type region of the diode.

8. The apparatus of claim 7, wherein the matrix comprises a gallium alloy and the n-type and p-type regions comprise gallium-aluminum-nitride alloys.

9. The apparatus of claim 1, further comprising:
a laser having a Fabry-Perot cavity and an optical gain medium therein, the optical gain medium comprising the matrix and quantum dots of the light-emitting diode.

10. The apparatus of claim 9, wherein the diode is configured to generate light in a telecommunication wavelength window in response to being electrically pumped.

11. A method of fabrication, comprising:
growing a plurality of quantum dots of a first group III-nitride alloy over a crystalline substrate; and
growing a capping layer of a different second group III-nitride alloy to cover the quantum dots, portions of the layer being laterally interposed between the quantum dots.

12. The method of claim 11, wherein the quantum dots comprise indium.

13. The method of claim 12, wherein the second group III-nitride comprises gallium.

14. The method of claim 12, wherein the growing a layer includes maintaining the substrate at a temperature of less than about 600° C.

15. The method of claim 11, further comprising:
growing another plurality of quantum dots of the first group III-nitride alloy on an exposed surface of the layer; and
growing another layer of a group III-nitride alloy over the another plurality of quantum dots, the another layer comprising a group III-nitride alloy different from the first group-III nitride alloy.

16. The method of claim 14, further comprising:
growing another layer of a group III-nitride alloy over the capping layer, the growing another layer being performed at a temperature of at least 650° C.

17. An apparatus comprises:
a light-emitting diode having a semiconductor stack located therein; and
wherein the stack has an n-type layer of a group III-nitride alloy, a p-type layer of a group III-nitride alloy, and a plurality of quantum dots of a group III-nitride alloy; and
wherein the quantum dots are located between the layers and comprise an indium alloy that differs from the group III-nitride alloys of the layers.

18. The apparatus of claim 17, wherein each layer includes an alloy of gallium.

19. The apparatus of claim 18, wherein the quantum dots are distributed in a matrix to form a vertical stack along a direction between an n-type and p-type layers, the matrix having a higher refractive index than the alloys of the layers.

20. The apparatus of claim 18, further comprising:
a laser having a Fabry-Perot cavity and an optical gain medium therein, the optical gain medium comprising the quantum dots of the diode.
